(19) United States
(12) Patent Application Publication
(10) Pub. No.: US 2024/0290623 A1
(43) Pub. Date: Aug. 29, 2024

(54) PROCESSING METHODS TO IMPROVE ETCHED SILICON-AND-GERMANIUM-CONTAINING MATERIAL SURFACE ROUGHNESS

(71) Applicant: Applied Materials, Inc., Santa Clara, CA (US)

(72) Inventors: Bin Yao, Santa Clara, CA (US); Zihui Li, Santa Clara, CA (US); Jiayin Huang, Fremont, CA (US); Anchuan Wang, San Jose, CA (US); Chia-Ling Kao, San Jose, CA (US); Nitin K. Ingle, San Jose, CA (US)

(73) Assignee: Applied Materials, Inc., Santa Clara, CA (US)

(21) Appl. No.: 18/115,269

(22) Filed: Feb. 28, 2023

(51) Int. Cl. H01L 21/3065; H01J 37/32

(52) U.S. Cl. CPC H01L 21/3065; H01J 37/32357; H01J 37/32816; H01J 2237/182; H01J 2237/334

(57) ABSTRACT

Exemplary semiconductor processing methods may include providing a pre-treatment precursor to a processing a remote plasma system of a semiconductor processing chamber. The methods may include generating plasma effluents of the pre-treatment precursor in the remote plasma system. The methods may include flowing plasma effluents of the pre-treatment precursor to a processing region of the semiconductor processing chamber. A substrate including alternating layers of material may be disposed within the processing region. The alternating layers of material may include a silicon-and-germanium-containing material. The methods may include contacting the substrate with the plasma effluents of the pre-treatment precursor. The methods may include etching the silicon-and-germanium-containing material. The methods may include providing a post-treatment precursor to the processing region. The methods may include contacting the substrate with the post-treatment precursor. The methods may include removing the portion of the silicon-and-germanium-containing material.

### TECHNICAL FIELD

The present technology relates to semiconductor processes and equipment. More specifically, the present technology relates to laterally etching silicon-and-germanium-containing material in vertical structures.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a pre-treatment precursor to a processing a remote plasma system of a semiconductor processing chamber. The methods may include generating plasma effluents of the pre-treatment precursor in the remote plasma system. The methods may include flowing plasma effluents of the pre-treatment precursor to a processing region of the semiconductor processing chamber. A substrate including alternating layers of material may be disposed within the processing region. The alternating layers of material may include a silicon-and-germanium-containing material. The methods may include contacting the substrate with the plasma effluents of the pre-treatment precursor. The contacting may remove a residue from a surface of the silicon-and-germanium-containing material. The methods may include etching the silicon-and-germanium-containing material. The methods may include providing a post-treatment precursor to the processing region of the semiconductor processing chamber. The methods may include contacting the substrate with the post-treatment precursor. The contacting may oxidize a portion of the silicon-and-germanium-containing material. The methods may include removing the portion of the silicon-and-germanium-containing material

In some embodiments, the pre-treatment precursor may be or include a hydrogen-containing precursor, a nitrogen-containing precursor, or an oxygen-containing precursor. A plasma power may be maintained at less than or about 5,000 W in the remote plasma system while generating plasma effluents of the pre-treatment precursor. The methods may include providing an inert precursor with the treatment precursor, the post-treatment precursor, or both. The post-treatment precursor comprises one or more of steam (H₂O), hydrogen peroxide (H₂O₂), or molecular oxygen (O₂). The alternating layers of material further include a silicon-containing material. The residue may be or include a carbon-containing material. A temperature within the semiconductor processing chamber may be maintained at greater than or about 100° C. A pressure within the semiconductor processing chamber may be maintained at less than or about 5 Torr. The methods may include generating plasma effluents of the post-treatment precursor. Subsequent to removing the portion of the silicon-and-germanium-containing material, a 3σ average surface roughness (Rₐ) of the silicon-and-germanium-containing material may be less than or about 5 nm.

Some embodiments of the present technology may encompass semiconductor processing methods. The methods may include etching a silicon-and-germanium-containing material from a substrate disposed within a processing region of a semiconductor processing chamber. The silicon-and-germanium-containing material may be one material of one or more alternating layers of material on the substrate. The silicon-and-germanium-containing material may be characterized by a first average surface roughness (Rₐ). The methods may include providing a treatment precursor to the processing region of the semiconductor processing chamber. The methods may include contacting the substrate with the treatment precursor. The contacting may oxidize a portion of the silicon-and-germanium-containing material. The methods may include removing the portion of the silicon-and-germanium-containing material.

In some embodiments, the average surface roughness (Rₐ) of the silicon-and-germanium-containing material may be improved by greater than or about 10% relative to the first average surface roughness (Rₐ). A temperature within the semiconductor processing chamber may be maintained at greater than or about 100° C. A pressure within the semiconductor processing chamber may be maintained at less than or about 5 Torr. The treatment precursor may include one or more of steam (H₂O), hydrogen peroxide (H₂O₂), or molecular oxygen (O₂). The methods may include providing an inert precursor with the treatment precursor. The methods may include, prior to etching the silicon-and-germanium-containing material, removing a native oxide from the silicon-and-germanium-containing material.

Some embodiments of the present technology may encompass semiconductor processing method. The methods may include etching a silicon-and-germanium-containing material from a substrate disposed within a processing region of a semiconductor processing chamber. The silicon-and-germanium-containing material may be one material of one or more alternating layers of material on the substrate. The methods may include providing a treatment precursor to the processing region of the semiconductor processing chamber. The methods may include contacting the substrate with the treatment precursor. The contacting may oxidize a portion of the silicon-and-germanium-containing material. The methods may include halting a flow of the treatment precursor. The methods may include removing the portion of the silicon-and-germanium-containing material.

In some embodiments, the methods may include, subsequent to halting the flow of the treatment precursor, transferring the substrate to a second processing region of a second semiconductor processing chamber. The methods may include, prior to etching the silicon-and-germanium-containing material, removing a native oxide from the silicon-and-germanium-containing material.

Such technology may provide numerous benefits over conventional systems and techniques. For example, the processes may remove residue from silicon-and-germanium-containing material prior to etching operations. Additionally, the removal of residue from the silicon-and-germanium-containing material may result in a more uniform etch resulting in an etched silicon-and-germanium-containing material with desirable surface roughness. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to embodiments of the present technology.

FIG. 2A shows a schematic cross-sectional view of an exemplary processing chamber according to embodiments of the present technology.

FIG. 2B shows a detailed view of a portion of the processing chamber illustrated in

FIG. 2A according to embodiments of the present technology.

FIG. 3 shows a bottom plan view of an exemplary showerhead according to embodiments of the present technology.

FIG. 4 shows exemplary operations in a method according to embodiments of the present technology.

FIGS. 5A-5C show cross-sectional views of substrates being processed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning to gate-all-around (GAA) transistors, many process operations are modified from more conventional fin field-effect (FinFET) transistors. Additionally, as structures continue to reduce in size, the thicknesses of material layers reduce and the aspect ratios of memory holes and other structures increase, sometimes dramatically.

During GAA processing, alternating layers of material are deposited on a substrate, such as alternating layers of silicon-containing material and silicon-and-germanium-containing material. In forming the transistor, memory holes or trenches may be formed through the alternating layers of material. During GAA processing, the silicon-and-germanium-containing material may be recessed from within the memory holes or trenches to form material that will serve as nanowires/nanosheets.

Because of the high aspect ratios of these memory holes or trenches, forming the memory holes or trenches may leave a residue on sidewalls. In embodiments where the precursors used to etch the memory holes or trenches includes a carbon-containing precursor, some carbon-containing material may deposit on exposed surfaces of the alternating layers of material. Specifically, carbon-containing material may form on exposed surfaces of the silicon-and-germanium-containing material as a residue. The residue may frustrate the subsequent recessing of the silicon-and-germanium-containing material. The residue may act as a mask that prevents the etching precursors from uniformly recessing the silicon-and-germanium-containing material. Accordingly, conventional technologies may struggle to uniformly recess the silicon-and-germanium-containing material due to the presence of residue on exposed surfaces of the silicon-and-germanium-containing material. The non-uniform recessing may result in an increased average surface roughness (Rₐ) of the etched silicon-and-germanium-containing material. This increased average surface roughness (Rₐ) of the etched silicon-and-germanium-containing material may undesirably affect electrical and/or mechanical properties of the silicon-and-germanium-containing material.

The present technology overcomes these issues by performing a treatment after formation of the memory holes or trenches through the alternating layers of material. The treatment may include forming plasma effluents of a treatment precursor and contacting the substrate with the treatment precursor. The treatment precursor and plasma effluents thereof, if formed, may selectively remove residue from the silicon-and-germanium-containing material that is to be recessed. By removing residue from the silicon-and-germanium-containing material, a more uniform etch to recess the silicon-and-germanium-containing material may be accomplished. Thus, the etched silicon-and-germanium-containing material may be characterized by a reduced average surface roughness (Rₐ) compared to conventional technologies.

Although the remaining disclosure will routinely identify specific etching processes utilizing the disclosed technology, it will be readily understood that the systems and methods are equally applicable to etching processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the operations described.

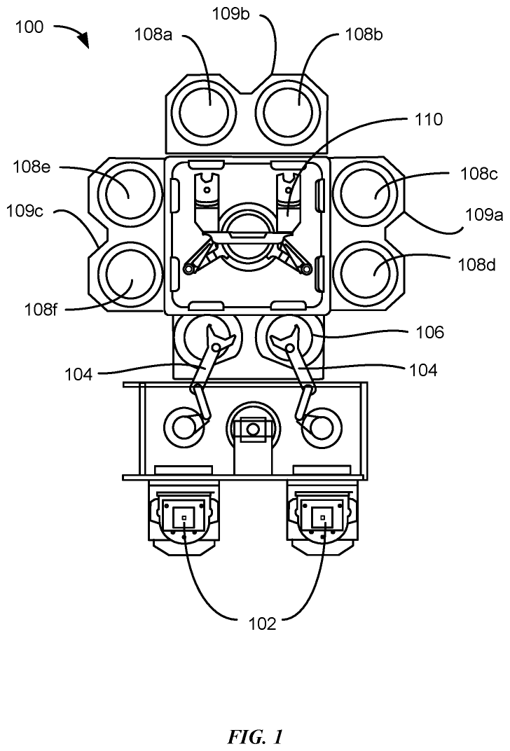

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

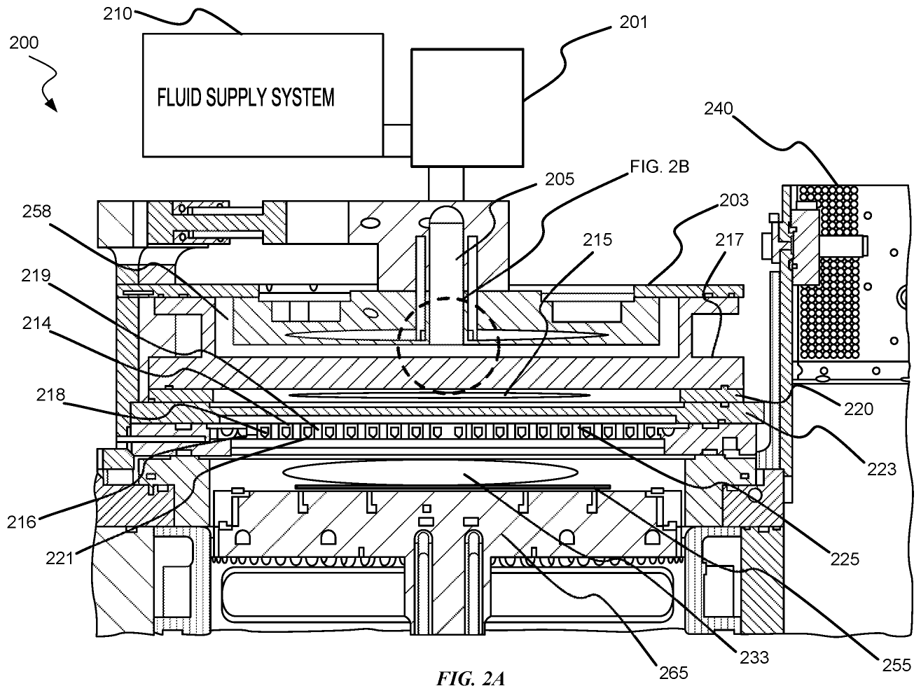

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100°° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiGeₓ:SiOₓ etch ratios, SiGeₓ: Si etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which materials may be etched increase. Accordingly, an exposed region of material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

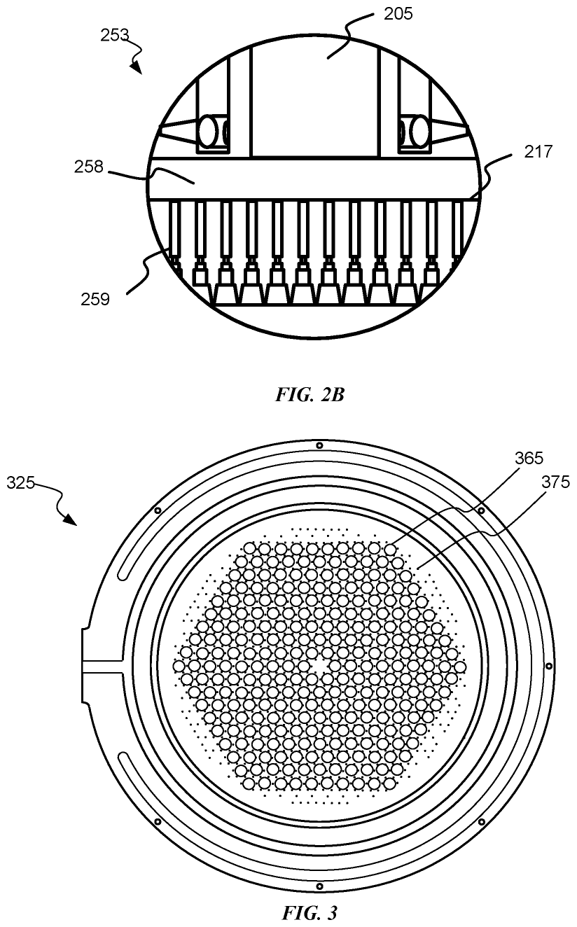

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

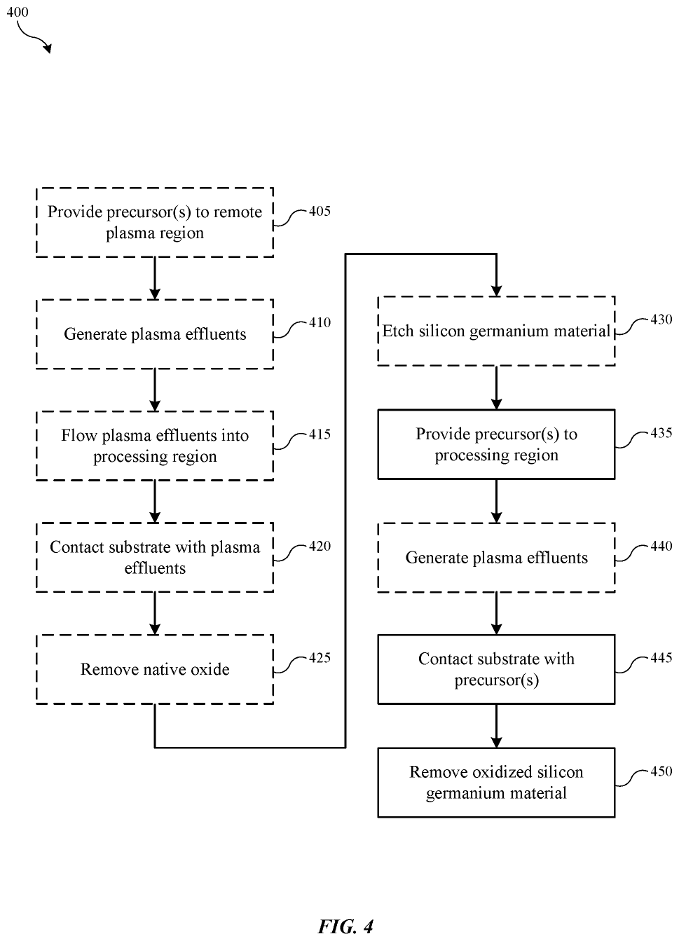

The chambers discussed previously may be used in performing exemplary methods including etching methods. Turning to FIG. 4 is shown exemplary operations in a method 400 according to embodiments of the present technology. Prior to the first operation of the method a substrate may be processed in one or more ways before being placed within a processing region of a chamber in which method 400 may be performed. For example, alternating layers of material may be formed on the substrate and then one or more memory holes or trenches may be formed through the alternating layers. The alternating layers may include any number of materials, and may include alternating layers of a silicon-containing material and a silicon-and-germanium-containing material. Although the remaining disclosure will discuss silicon-containing material and silicon-and-germanium-containing material, any other known materials used in these two layers may be substituted for one or more of the layers. Some or all of these operations may be performed in chambers or system tools as previously described, or may be performed in different chambers on the same system tool, which may include the chamber in which the operations of method 400 are performed.

The method 400 may include providing a first treatment precursor, such as a pre-treatment precursor or pre-etching precursor, to a remote plasma region of a semiconductor processing chamber at operation 405. In some embodiments, an inert precursor may be provided with the treatment precursor. An exemplary chamber may be chamber 200 previously described, which may include one or both of the RPS unit 201 or first plasma region 215. Either or both of these regions may be the remote plasma region used in operation 405. A plasma may be generated within the remote plasma region at operation 410, which may generate plasma effluents of the treatment precursor. The plasma effluents may be flowed to a processing region of the chamber at operation 415. The plasma effluents may interact with and contact the substrate in the processing region at operation 420, which may include one or more memory holes or trenches formed through the alternating layers, such alternating layers of silicon-containing material and silicon-and-germanium-containing material. The contact between the precursor and the substrate may remove a residue from a surface of the silicon-and-germanium-containing material. The operations to develop the substrate, such as an etching operation to form the one or more memory holes or trenches through alternating layers of material, may leave any number of residues on the materials. For example, the etching to form the one or more memory holes or trenches may leave a carbon-containing material on the silicon-and-germanium-containing material. This carbon-containing material on the silicon-and-germanium-containing material may impact subsequent operations, such as an operation to laterally etch the silicon-and-germanium-containing material. Accordingly, the contacting at operation 420 may remove at least a portion of residue on the silicon-and-germanium-containing material that may allow for a better etch of the silicon-and-germanium-containing material. In embodiments, after removing residue at operation 420, method 400 may include removing a native oxide from the substrate, such as from the silicon-and-germanium-containing material, at optional operation 425. Method 400 may also include etching the silicon-and-germanium-containing material to recess the etching the silicon-and-germanium-containing material from the one or more memory holes or trenches at optional operation 430. In embodiments, subsequent to etching the silicon-and-germanium-containing material, method 400 may include providing a second treatment precursor, such as a post-treatment precursor or post-etching precursor, to the processing region of the semiconductor processing chamber at operation 435. Plasma effluents of the treatment precursor at optional operation 440. Method 400 may include contacting the substrate with the treatment precursor at operation 445. The contacting at operation 445 may oxidize a portion of the silicon-and-germanium-containing material. To improve surface roughness of the silicon-and-germanium-containing material, operation 450 of method 400 may include removing the portion of the silicon-and-germanium-containing material, or the silicon-and-germanium-containing material oxidized at operation 445.

Method 400 may involve removing residue from exposed surface of silicon-and-germanium-containing material in the one or more memory holes or trenches in order to provide a more uniform and less rough etch of the silicon-and-germanium-containing material in the alternating layers of material. As previously discussed, forming the one or more memory holes or trenches may leave a residue on exposed surfaces due to the precursors used to etch the alternating layers of material. In embodiments, the precursors used to etch the alternating layers of material may include a carbon-containing precursor, for example, that may leave carbon-containing material on sidewalls of the one or more memory holes or trenches, such as on exposed surfaces of the silicon-and-germanium-containing material. In some semiconductor structures, such as GAA transistors, the silicon-and-germanium-containing material may be recessed relative to the other material in the alternating layers, such as the silicon-containing material. However, the presence of residue, such as carbon-containing material, may frustrate the etch to recess the silicon-and-germanium-containing material. The carbon-containing material may act as a discontinuous mask and the silicon-and-germanium-containing material may be etched unevenly, resulting in a roughened surface. Method 400 may include removing residue from exposed surfaces of the silicon-and-germanium-containing material to permit increased uniformity of the subsequent etch to recess the silicon-and-germanium-containing material. Accordingly, method 400 may permit a 3σ average surface roughness (Rₐ) of the silicon-and-germanium-containing material to be maintained at less than or about 5 nm or less.

The diameter or width of exemplary memory holes or trenches may be a few tens or nanometers or less, while the height of the memory holes or trenches may be on the order or a few microns or more. This may produce aspect ratios or height to width ratios of greater than 20:1, greater than 50:1, greater than 75:1, greater than 100:1, or even greater. The present technology may be applied to, for example, memory applications, to GAA transistors, and to logic applications. Accordingly, in embodiments over 2 layers, over 3 layers, over 4 layers, over 5 layers, over 10 layers, over 15 layers, over 20 layers, over 25 layers, over 50 layers, over 75 layers, or over one hundred layers of alternating layers of material may be present within each memory hole trench. In embodiments, prior to method 400, a 3σ average surface roughness (Rₐ) of the silicon-and-germanium-containing material under the residue may be greater than or about 4.5 nm, and may be greater than or about 5 nm, greater than or about 5.5 nm, greater than or about 6 nm, greater than or about 6.5 nm, greater than or about 7 nm, greater than or about 7.5 nm, greater than or about 8 nm, greater than or about 8.5 nm, or more.

Precursors used in the method may include a treatment precursor as well as optionally an inert precursor. An exemplary treatment precursor may be a hydrogen-containing precursor, a nitrogen-containing precursor, an oxygen-containing precursor, or combinations thereof, which may be flowed into the remote plasma region, which may be separate from, but fluidly coupled with, the processing region. The hydrogen-containing precursor may be or include, for example, molecular hydrogen (H₂), ammonia (NH₃), or any other hydrogen-containing precursor used or useful in semiconductor processing. The nitrogen-containing precursor may be or include, for example, molecular nitrogen (N₂), ammonia (NH₃), or any other nitrogen-containing precursor used or useful in semiconductor processing. The oxygen-containing precursor may be or include, for example, molecular oxygen (O₂), or any other oxygen-containing precursor used or useful in semiconductor processing. The treatment precursor may be provided with an inert precursor in some embodiments. The inert precursor may be or include, for example, argon, helium, xenon, or other noble, inert, or useful precursors. The inert precursor may be used to dilute the treatment precursor, which may further reduce etching rates to allow adequate diffusion through the trench, or to assist in distributing the treatment precursor throughout the processing region.

A flow rate of the treatment precursor and the inert precursor, if present, may be sufficient to provide adequate distribution to treat the entire substrate. In embodiments, a flow rate of the treatment precursor to the remote plasma system may be greater than or about 1 sccm, and may be greater than or about 10 sccm, greater than or about 50 sccm, greater than or about 100 sccm, greater than or about 250 sccm, greater than or about 500 sccm, greater than or about 1,000 sccm, greater than or about 1,500 sccm, greater than or about 2,000 sccm, greater than or about 2,500 sccm, greater than or about 3,000, greater than or about 3,500, greater than or about, 4,000, or higher. Additionally, a flow rate of the inert precursor, which may dilute and/or distribute the treatment precursor or plasma effluents thereof may be greater than or about 100 sccm, and may be greater than or about 250 sccm, greater than or about 500 sccm, greater than or about 750 sccm, greater than or about 1,000 sccm, greater than or about 2,500 sccm, greater than or about 5,000 sccm, greater than or about 7,500 sccm, greater than or about 10,000 sccm, or higher.

The plasma effluents of the treatment precursor and the inert precursor, if present, may be generated at a plasma power of less than or about 5,000 W, and may be generated at less than or about 4,750 W, less than or about 4,500 W, less than or about 4,250 W, less than or about 4,000 W, less than or about 3,750 W, less than or about 3,500 W, less than or about 3,250 W, less than or about 3,000 W, less than or about 2,750 W, less than or about 2,500 W, less than or about 2,250 W, less than or about 2,000 W, less than or about 1,750 W, less than or about 1,500 W, less than or about 1,250 W, less than or about 1,000 W, less than or about 750 W, less than or about 500 W, less than or about 250 W, or less. By generating the plasma effluents in the remote plasma system, a portion of ions present in the generated plasma effluents may be filtered before being flowed to the processing region. This filtration may limit bombardment and damage to the substrate and materials deposited thereon.

The substrate may be contacted with the plasma effluents of the treatment precursor for a sufficient period of time to treat the residue, such as carbon-containing material, on the silicon-and-germanium-containing material. In embodiments, the period of time may be greater than or about 3 seconds, greater than or about 5 seconds, greater than or about 10 seconds, greater than or about 20 seconds, greater than or about 30 seconds, greater than or about 40 seconds, greater than or about 50 seconds, greater than or about 1 minute, greater than or about 2 minutes, greater than or about 3 minutes, greater than or about 5 minutes, or higher. At a period of time greater than or about 3 seconds, greater than or about 85%of the residue may be removed from the silicon-and-germanium-containing material, and greater than or about 90%, greater than or about 95%, greater than or about 97%, greater than or about 99%, greater than or about 99.9%, or higher, or all of the residue may be removed from the silicon-and-germanium-containing material.

As previously discussed, method 400 may include removing a native oxide from the material on the substrate, such as from the silicon-and-germanium-containing material, at optional operation 425. Optional operation 425 may be performed in the same semiconductor processing chamber as operations 405-420, or the substrate may be transferred to a second processing region of a second semiconductor processing chamber to remove the native oxide. However, the second semiconductor processing chamber may be on the same processing system, such as processing system 100, as the semiconductor processing chamber used during operations 405-420. Additionally, method 400 may include etching the silicon-and-germanium-containing material at optional operation 430. Etching the silicon-and-germanium-containing material may be performed as an operation in forming a GAA transistor. Optional operation 430 may be performed in the same semiconductor processing chamber as operations 405-420 and/or optional operation 425, or the substrate may be transferred to a third processing region of a third semiconductor processing chamber to remove the native oxide. However, the third semiconductor processing chamber may be on the same processing system, such as processing system 100, as the semiconductor processing chamber used during operations 405-420 and/or the semiconductor processing chamber used during optional operation 425.

Removing residue from exposed surface of silicon-and-germanium-containing material in the one or more memory holes or trenches may provide a more uniform and less rough etch of the silicon-and-germanium-containing material in the alternating layers of material. In embodiments, the average surface roughness (Rₐ) of the silicon-and-germanium-containing material may be improved by greater than or about 5%, and may be improved by greater than or about 10%, greater than or about 15%, greater than or about 20%, greater than or about 25%, greater than or about 30%, greater than or about 35%, greater than or about 40%, or more. For example, the 3σ average surface roughness (Rₐ) of the silicon-and-germanium-containing material, subsequent etching of the silicon-and-germanium-containing material, may be less than or about 5 nm, and may be less than or about 4.9 nm, less than or about 4.8 nm, less than or about 4.7 nm, less than or about 4.6 nm, less than or about 4.5 nm, less than or about 4.3 nm, less than or about 4.2 nm, less than or about 4.1 nm, less than or about 4 nm, less than or about 3.9 nm, less than or about 3.8 nm, less than or about 3.7 nm, less than or about 3.6 nm, less than or about 3.5 nm, less than or about 3.3 nm, less than or about 3.2 nm, less than or about 3.1 nm, less than or about 3 nm, or less. In conventional technologies where residue is not removed from exposed surfaces of the silicon-and-germanium-containing material prior to etching, the 3σ average surface roughness (Rₐ) of the silicon-and-germanium-containing material, subsequent etching of the silicon-and-germanium-containing material, may be greater than or about 5 nm or more.

In embodiments, method 400 may include providing a treatment precursor to the processing region of the semiconductor processing chamber at operation 435. In some embodiments, an inert precursor may be provided with the treatment precursor. An exemplary treatment precursor may be an oxygen-containing precursor, which may be flowed into the processing region or the remote plasma region, which may be separate from, but fluidly coupled with, the processing region. The treatment precursor may be or include, for example, molecular oxygen (O₂), steam (H₂O), hydrogen peroxide (H₂O₂), or any other oxygen-containing precursor used or useful in semiconductor processing. A diluent precursor, such as molecular hydrogen (H₂) may be provided with the oxygen-containing precursor to reduce oxidative effect of the oxygen-containing precursor and/or increase oxidation selectivity. In embodiments, steam (H₂O), molecular oxygen (O₂) and molecular hydrogen (H₂), or hydrogen peroxide (H₂O₂) may have reduced oxidation effects compared to molecular oxygen (O₂). Additionally, a flow rate ratio of the oxygen-containing precursor and, if present, the diluent precursor may be adjusted to tune oxidative effect of the oxygen-containing precursor and/or oxidation selectivity. The inert precursor may be or include, for example, argon, helium, xenon, or other noble, inert, or useful precursors. The inert precursor may be used to dilute the treatment precursor, which may further reduce etching rates to allow adequate diffusion through the trench, or to assist in distributing the treatment precursor throughout the processing region.

A flow rate of the treatment precursor and the inert precursor, if present, may be sufficient to provide adequate distribution to treat the entire substrate. In embodiments, a flow rate of the treatment precursor to the processing region or the remote plasma system may be greater than or about 1 sccm, and may be greater than or about 10 sccm, greater than or about 50 sccm, greater than or about 100 sccm, greater than or about 250 sccm, greater than or about 500 sccm, greater than or about 1,000 sccm, greater than or about 1,500 sccm, greater than or about 2,000 sccm, greater than or about 2,500 sccm, greater than or about 3,000, greater than or about 3,500, greater than or about, 4,000, or higher. Additionally, a flow rate of the inert precursor, which may dilute and/or distribute the treatment precursor or plasma effluents thereof may be greater than or about 100 sccm, and may be greater than or about 250 sccm, greater than or about 500 sccm, greater than or about 750 sccm, greater than or about 1,000 sccm, greater than or about 2,500 sccm, greater than or about 5,000 sccm, greater than or about 7,500 sccm, greater than or about 10,000 sccm, or higher.

In some embodiments, plasma effluents of the treatment precursor may be generated at optional operation 440. However, it is contemplated that plasma effluents may not be formed of the treatment precursor and a plasma-free or thermal post-treatment may be performed. As discussed, the plasma effluents may be generated in the processing region or, similar to the pre-treatment precursor, in the remote plasma system. In embodiments, the plasma effluents of the treatment precursor and the inert precursor, if present, may be generated at a plasma power of less than or about 5,000 W, and may be generated at less than or about 4,750 W, less than or about 4,500 W, less than or about 4,250 W, less than or about 4,000 W, less than or about 3,750 W, less than or about 3,500 W, less than or about 3,250 W, less than or about 3,000 W, less than or about 2,750 W, less than or about 2,500 W, less than or about 2,250 W, less than or about 2,000 W, less than or about 1,750 W, less than or about 1,500 W, less than or about 1,250 W, less than or about 1,000 W, less than or about 750 W, less than or about 500 W, less than or about 250 W, or less. Compared to the pre-treatment precursor, plasma effluents of the post-treatment may be generated at a lower plasma power. By generating plasma effluents of the post-treatment at a lower plasma power, bombardment and damage to the substrate and materials deposited thereon may be limited.

Method 400 may include contacting the substrate with the treatment precursor at operation 445. The contacting may continue for a sufficient period of time to oxidize a portion of the silicon-and-germanium-containing material. In embodiments, the period of time may be greater than or about 3 seconds, greater than or about 5 seconds, greater than or about 10 seconds, greater than or about 20 seconds, greater than or about 30 seconds, greater than or about 40 seconds, greater than or about 50 seconds, greater than or about 1 minute, greater than or about 2 minutes, greater than or about 3 minutes, greater than or about 5 minutes, or higher. Similarly, the period of time may be less than or about 5 minutes, less than or about 3 minutes, less than or about 2 minutes, less than or about 1 minute, less than or about 50 seconds, less than or about 40 seconds, less than or about 30 seconds, less than or about 20 seconds, less than or about 10 seconds, less than or about 5 seconds, less than or about 3 seconds, or less.

By contacting the substrate with the treatment precursor, germanium and/or silicon in the silicon-and-germanium-containing material may bond with oxygen to oxidize a portion of the silicon-and-germanium-containing material. Without being bound by any particular theory, it is believed Si-Ge bonds in the silicon-and-germanium-containing material may break easier than Si-Si bonds in neighboring silicon-containing material, and the silicon-and-germanium-containing material may oxidize easier than neighboring silicon-containing material. Additionally, by operating at temperature ranges discussed below, the silicon-and-germanium-containing material may have a higher oxidation rate than neighboring silicon-containing material. Rougher portions of the silicon-and-germanium-containing material, which may be characterized by greater nonuniformity, may oxidize greater or to a further depth than less rough portions of the silicon-and-germanium-containing material.

At operation 450, method 400 may include removing the portion of the silicon-and-germanium-containing material, such as the portion of the silicon-and-germanium-containing material oxidized at operation 445. In embodiments, prior to removing the portion of the silicon-and-germanium-containing material, a flow of the treatment precursor may be halted. Operation 450 may be performed in the same semiconductor processing chamber as operations 435-445, or the substrate may be transferred to a fourth processing region of a fourth semiconductor processing chamber to remove the portion of the silicon-and-germanium-containing material. However, the fourth semiconductor processing chamber may be on the same processing system, such as processing system 100, as the semiconductor processing chamber used during operations 405-445. Removing the portion of the silicon-and-germanium-containing material may be performed using any dry etch or wet etch operation operable to remove oxidized silicon-and-germanium-containing material. By removing the portion of the silicon-and-germanium-containing material oxidized at operation 445, uniformity and average surface roughness (Rₐ) of the silicon-and-germanium-containing material may be achieved. As previously discussed, rougher portions of the surface of the silicon-and-germanium-containing material may be oxidized to a greater degree. Therefore, by removing the oxidized portion of the silicon-and-germanium-containing material, roughness may be improved compared to the etched silicon-and-germanium-containing material.

Similar to removing residue from exposed surface of silicon-and-germanium-containing material, oxidizing the portion of the silicon-and-germanium-containing material and subsequently removing the oxidized portion may improve roughness of the silicon-and-germanium-containing material after etching. In embodiments, the average surface roughness (Rₐ) of the silicon-and-germanium-containing material may be improved by greater than or about 5%, and may be improved by greater than or about 10%, greater than or about 15%, greater than or about 20%, greater than or about 25%, greater than or about 30%, greater than or about 35%, greater than or about 40%, or more. For example, without pre-treating the silicon-and-germanium-containing material, the 3σ average surface roughness (Rₐ) of the silicon-and-germanium-containing material, after etching of the silicon-and-germanium-containing material, may be greater than or about 5 nm or more. By oxidizing the portion of the silicon-and-germanium-containing material and subsequently removing the oxidized portion, the 3σ average surface roughness (Rₐ) of the silicon-and-germanium-containing material, may be improved to less than or about 5 nm, and may be less than or about 4.9 nm, less than or about 4.8 nm, less than or about 4.7 nm, less than or about 4.6 nm, less than or about 4.5 nm, less than or about 4.3 nm, less than or about 4.2 nm, less than or about 4.1 nm, less than or about 4 nm, less than or about 3.9 nm, less than or about 3.8 nm, less than or about 3.7 nm, less than or about 3.6 nm, less than or about 3.5 nm, less than or about 3.3 nm, less than or about 3.2 nm, less than or about 3.1 nm, less than or about 3 nm, or less. Combining the pre-treatment and post-treatment may further improve the 3σ average surface roughness (Rₐ) of the silicon-and-germanium-containing material.

Process conditions may also impact the operations performed in method 400 as well as other etching methods according to the present technology. Each of the operations of method 400 may be performed during a constant temperature in embodiments, while in some embodiments the temperature may be adjusted during different operations. For example, the substrate, pedestal, or chamber temperature while contacting the substrate with the plasma effluents may be maintained between about 25° C. and about 500° C. in embodiments. The temperature may also be maintained at less than or about 480° C., less than or about 460° C., less than or about 440° C., less than or about 420° C., less than or about 400° C., less than or about 380° C., less than or about 360° C., less than or about 350° C., less than or about 340° C., less than or about 330° C., less than or about 320° C., less than or about 310° C., less than or about 300° C., less than or about 280° C., less than or about 260° C., less than or about 240° C., less than or about 220° C., less than or about 200° C., less than or about 180° C., less than or about 160° C., less than or about 140° C., less than or about 120° C., less than or about 100° C., or lower. In embodiments, the temperature may also be maintained at greater than or about or about 100° C., greater than or about or about 120° C., greater than or about or about 140°° C., greater than or about or about 160° C., greater than or about or about 180°° C., greater than or about or about 200° C., greater than or about or about 220° C., greater than or about or about 240° C., greater than or about or about 260° C., greater than or about or about 280° C., greater than or about or about 300° C., greater than or about or about 320° C., greater than or about or about 340° C., greater than or about or about 360° C., greater than or about or about 380° C., greater than or about or about 400° C., greater than or about or about 420° C., greater than or about or about 440° C., greater than or about or about 460° C., greater than or about or about 480° C., greater than or about or about 500° C., or higher. Temperature may affect the etching process itself, and higher temperature may produce higher reactivity between the treatment precursor and the residue on the silicon-and-germanium-containing material. Similarly, lower temperatures may slow the removal of the residue on the silicon-and-germanium-containing material due to poor reactivity. Thus, in some embodiments, maintaining a temperature at greater than or about 100° C. may provide more uniform residue removal from the silicon-and-germanium-containing material.

The pressure within the chamber may also affect the operations performed, and in embodiments the pressure within the semiconductor processing chamber may be maintained at less than about 5 Torr, less than or about 4.5 Torr, less than or about 4 Torr, less than or about 3.5 Torr, less than or about 3 Torr, less than or about 2.5 Torr, less than or about 2 Torr, less than or about 1.5 Torr, less than or about 1 Torr, less than or about 0.5 Torr, less than or about 0.3 Torr, less than or about 0.2 Torr, less than or about 0.1 Torr, less than or about 0.85 Torr, or less. In embodiments a pressure below or about 3 Torr may allow the precursors or plasma effluents thereof to more easily flow into the trenches or memory holes. Accordingly, a lower pressure may permit increased removal rates of residue on the silicon-and-germanium-containing material due to lower recombination of plasma radicals within the processing region.

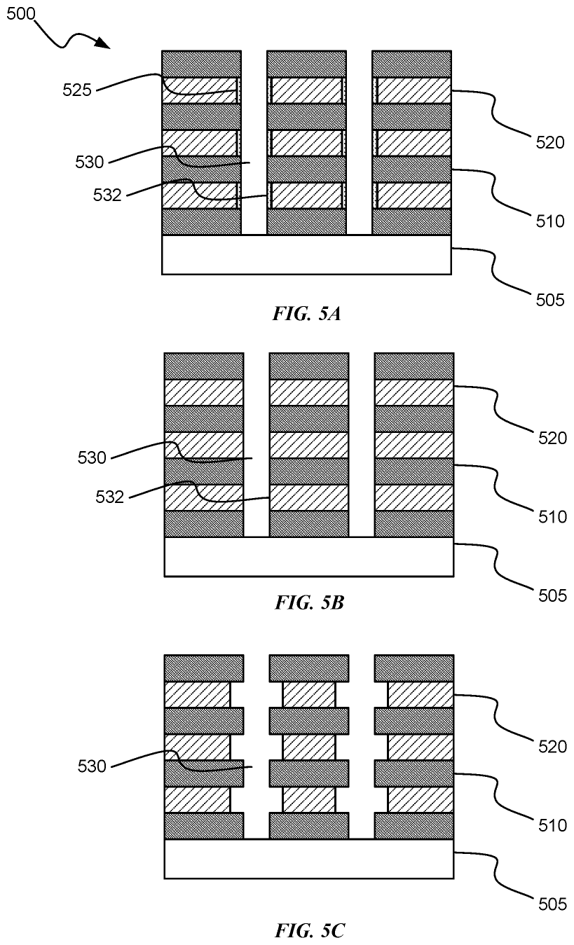

Turning to FIGS. 5A-5C are shown cross-sectional views of structure 500 being processed according to embodiments of the present technology. As illustrated in FIG. 5A substrate 505 may have plurality of stacked layers overlying the substrate, which may be silicon-containing material, silicon-and-germanium-containing material, or other substrate materials. The alternating layers of material may include materials suitable for GAA transistors, such as silicon-containing material 510 alternating with silicon-and-germanium-containing material 520. The silicon-and-germanium-containing material 520 may be or include material that will be recessed to produce nanowires/nanosheets in GAA transistors. Although illustrated with only 7 layers of material, exemplary structures may include any of the numbers of layers previously discussed. Memory holes or trenches 530 may be defined through the stacked structure to the level of substrate 505. Memory holes or trenches 530 may be defined by sidewalls 532 that may be composed of the alternating layers of silicon-containing material 510 and silicon-and-germanium-containing material 520. Residue 525 may be present on the silicon-and-germanium-containing material 520 after forming memory holes or trenches 530. The residue 525 may be a carbon-containing material and may be resultant of the precursors used to form memory holes or trenches 530.

In FIG. 5B may be illustrated a structure after some operations of methods according to the present technology have been performed, such as discussed with respect to FIG. 4 above. The residue 525 present on the silicon-and-germanium-containing material 520 as shown in FIG. 5A may be removed to expose the underlying silicon-and-germanium-containing material 520. While FIG. 5B depicts that all residue 525 is removed, it is contemplated that not all of the residue 525 may be removed and that some residue 525 may still be present.

FIG. 5C illustrates a structure after further operations of methods according to the present technology have been performed, such as discussed with respect to FIG. 4 above. An etching operation may be performed to recess the silicon-and-germanium-containing material 520. The etching may recess a portion of the silicon-and-germanium-containing material 520, which may form nanowires/nanosheets of the silicon-and-germanium-containing material 520 useful in gate all around applications between neighboring silicon-containing material 510. In embodiments, the silicon-and-germanium-containing material 520 may be recessed less than about 10 nm or less. Substrate 505 may show minimal etching at the bottom of trenches 530. Subsequent etching, a portion of the silicon-and-germanium-containing material 520 may be oxidized and removed to further reduce surface roughness.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a pre-treatment precursor to a processing of a remote plasma system of a semiconductor processing chamber;
generating plasma effluents of the pre-treatment precursor in the remote plasma system;
flowing plasma effluents of the pre-treatment precursor to a processing region of the semiconductor processing chamber, wherein a substrate comprising alternating layers of material is disposed within the processing region, and wherein the alternating layers of material comprise a silicon-and-germanium-containing material;
contacting the substrate with the plasma effluents of the pre-treatment precursor, wherein the contacting removes a residue from a surface of the silicon-and-germanium-containing material;
etching the silicon-and-germanium-containing material;
providing a post-treatment precursor to the processing region of the semiconductor processing chamber;
contacting the substrate with the post-treatment precursor, wherein the contacting oxidizes a portion of the silicon-and-germanium-containing material; and
removing the portion of the silicon-and-germanium-containing material.

2. The semiconductor processing method of claim 1, wherein the pre-treatment precursor comprises a hydrogen-containing precursor, a nitrogen-containing precursor, or an oxygen-containing precursor.

3. The semiconductor processing method of claim 1, wherein a plasma power is maintained at less than or about 5,000 W in the remote plasma system while generating plasma effluents of the pre-treatment precursor.

4. The semiconductor processing method of claim 1, further comprising:
providing an inert precursor with the pre-treatment precursor, the post-treatment precursor, or both.

5. The semiconductor processing method of claim 1, wherein the post-treatment precursor comprises one or more of steam (H₂O), hydrogen peroxide (H₂O₂), or molecular oxygen (O₂).

6. The semiconductor processing method of claim 1, wherein the alternating layers of material further comprise a silicon-containing material.

7. The semiconductor processing method of claim 1, wherein the residue comprises a carbon-containing material.

8. The semiconductor processing method of claim 1, wherein a temperature within the semiconductor processing chamber is maintained at greater than or about 100° C.

9. The semiconductor processing method of claim 1, wherein a pressure within the semiconductor processing chamber is maintained at less than or about 5 Torr.

10. The semiconductor processing method of claim 1, further comprising:
generating plasma effluents of the post-treatment precursor.

11. The semiconductor processing method of claim 10, wherein, subsequent to removing the portion of the silicon-and-germanium-containing material, a 3σ average surface roughness (Rₐ) of the silicon-and-germanium-containing material is less than or about 5 nm.

12. A semiconductor processing method comprising:
etching a silicon-and-germanium-containing material from a substrate disposed within a processing region of a semiconductor processing chamber, wherein the silicon-and-germanium-containing material is one material of one or more alternating layers of material on the substrate, and wherein the silicon-and-germanium-containing material is characterized by a first average surface roughness (Rₐ);
providing a treatment precursor to the processing region of the semiconductor processing chamber;
contacting the substrate with the treatment precursor, wherein the contacting oxidizes a portion of the silicon-and-germanium-containing material; and
removing the portion of the silicon-and-germanium-containing material.

13. The semiconductor processing method of claim 12, wherein the average surface roughness (Rₐ) of the silicon-and-germanium-containing material is improved by greater than or about 10% relative to the first average surface roughness (Rₐ).

14. The semiconductor processing method of claim 12, wherein:
a temperature within the semiconductor processing chamber is maintained at greater than or about 100° C.; and
a pressure within the semiconductor processing chamber is maintained at less than or about 5 Torr.

15. The semiconductor processing method of claim 12, wherein the treatment precursor comprises one or more of steam (H₂O), hydrogen peroxide (H₂O₂), or molecular oxygen (O₂).

16. The semiconductor processing method of claim 12, further comprising:
providing an inert precursor with the treatment precursor.

17. The semiconductor processing method of claim 12, further comprising:
prior to etching the silicon-and-germanium-containing material, removing a native oxide from the silicon-and-germanium-containing material.

18. A semiconductor processing method comprising:
etching a silicon-and-germanium-containing material from a substrate disposed within a processing region of a semiconductor processing chamber, wherein the silicon-and-germanium-containing material is one material of one or more alternating layers of material on the substrate;
providing a treatment precursor to the processing region of the semiconductor processing chamber;
contacting the substrate with the treatment precursor, wherein the contacting oxidizes a portion of the silicon-and-germanium-containing material;
halting a flow of the treatment precursor; and
removing the portion of the silicon-and-germanium-containing material.

19. The semiconductor processing method of claim 18, further comprising:
subsequent to halting the flow of the treatment precursor, transferring the substrate to a second processing region of a second semiconductor processing chamber.

20. The semiconductor processing method of claim 18, further comprising:
prior to etching the silicon-and-germanium-containing material, removing a native oxide from the silicon-and-germanium-containing material.
